(19) United States
(12) Patent Application Publication
(10) Pub. No.: US 2024/0099021 A1
(43) Pub. Date: Mar. 21, 2024

(54) MAGNETIC MEMORY DEVICE

(71) Applicant: Kioxia Corporation, Tokyo (JP)

(72) Inventors: Naoki AKIYAMA, Seoul (KR); Kenichi YOSHINO, Seongnam-si Gyeonggi-do (KR); Kazuya SAWADA, Seoul (KR); Hyungjun CHO, Seoul (KR); Takuya SHIMANO, Seoul (KR)

(73) Assignee: Kioxia Corporation, Tokyo (JP)

(21) Appl. No.: 18/465,759

(22) Filed: Sep. 12, 2023

(30) Foreign Application Priority Data
Sep. 15, 2022 (JP) 2022-146920

(51) Int. Cl. H10B 61/00

(52) U.S. Cl. CPC H10B 61/10

(57) ABSTRACT

According to one embodiment, a magnetic memory device includes a lower insulating layer, first and second conductive portions provided in the lower insulating layer, first and second memory cells provided on the lower insulating layer and on the respective first and second conductive portions, and each including a magnetoresistance effect element, a switching element and a bottom electrode connected to corresponding one of the first and second conductive portions. As viewed from a third direction, a width of each of the first and second conductive portions is less than a width of a corresponding bottom electrode. The lower insulating layer has a void under a region between the first and second memory cells.

### CROSS-REFERENCE TO RELATED APPLICATIONS

This application is based upon and claims the benefit of priority from Japanese Patent Application No. 2022-146920, filed Sep. 15, 2022, the entire contents of which are incorporated herein by reference.

### FIELD

Embodiments described herein relate generally to a magnetic memory device.

### BACKGROUND

A magnetic memory device has been proposed in which a plurality of memory cells including magnetoresistance effect elements and selectors (switching elements) are integrated on a semiconductor substrate.

### BRIEF DESCRIPTION OF THE DRAWINGS

FIG. 1 is a perspective view schematically showing a basic configuration of a magnetic memory device according to the first embodiment.

FIG. 2A is a cross-sectional view schematically showing a detailed configuration of the magnetic memory device according to the first embodiment.

FIG. 2B is a planar pattern view schematically showing a detailed configuration of the magnetic memory device according to the first embodiment.

FIG. 3 is a cross-sectional view schematically showing a basic configuration of a magnetoresistance effect element of the magnetic memory device according to the first embodiment.

FIG. 4 is a cross-sectional view schematically showing a basic configuration of a selector of the magnetic memory device according to the first embodiment.

FIG. 5 is a schematic diagram showing current-voltage characteristics of the selector of the magnetic memory device of the first embodiment.

FIGS. 6A, 7A, 8A, 9A, 10A, 11A and 12A each are a cross-sectional view schematically illustrating a part of a method of manufacturing the magnetic memory device according to the first embodiment.

FIGS. 6B, 7B, 8B, 9B, 10B, 11B and 12B each are a plan view schematically illustrating the part of the method of manufacturing the magnetic memory device according to the first embodiment.

FIG. 13A is a cross-sectional view schematically showing a detailed configuration of a magnetic memory device according to the second embodiment.

FIG. 13B is a planar pattern view schematically showing a detailed configuration of the magnetic memory device according to the second embodiment.

FIGS. 14A, 15A, 16A, 17A, 18A, 19A and 20A each are a cross-sectional view schematically illustrating a part of a method of manufacturing the magnetic memory device according to the second embodiment.

FIGS. 14B, 15B, 16B, 17B, 18B, 19B and 20B each are a plan view schematically illustrating the part of the method of manufacturing the magnetic memory device according to the second embodiment.

### DETAILED DESCRIPTION

In general, according to one embodiment, a magnetic memory device includes: a lower insulating layer; a first lower conductive portion provided in the lower insulating layer; a second lower conductive portion provided in the lower insulating layer, and arranged to be apart from the first lower conductive portion and adjacent to the first lower conductive portion in a first direction; a first memory cell provided on the lower insulating layer and on the first lower conductive portion, and including a first magnetoresistance effect element, a first switching element and a first bottom electrode connected to the first lower conductive portion which are stacked in a second direction intersecting the first direction; a second memory cell provided on the lower insulating layer and on the second lower conductive portion, arranged adjacent to the first memory cell in the first direction, and including a second magnetoresistance effect element, a second switching element and a second bottom electrode connected to the second lower conductive portion which are stacked in the second direction, wherein as viewed from a third direction intersecting the first and second directions, a width of the first lower conductive portion in the first direction is less than a width of the first bottom electrode in the first direction, and a width of the second lower conductive portion in the first direction is less than a width of the second bottom electrode in the first direction, and the lower insulating layer has a void under a region between the first memory cell and the second memory cell.

Embodiments will be described hereinafter with reference to the accompanying drawings.

### First Embodiment

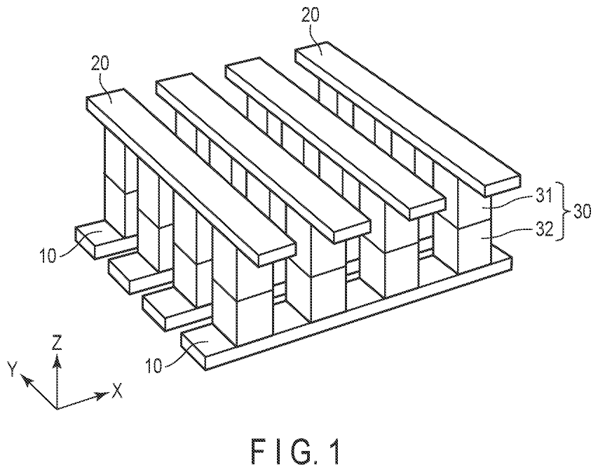

FIG. 1 is a perspective view schematically showing a basic configuration of a magnetic memory device according to the first embodiment.

The magnetic memory device shown in FIG. 1 is provided on a lower structure (not shown) including a semiconductor substrate (not shown) and includes a plurality of lower wiring lines 10 each extending along an X direction, a plurality of upper wiring lines 20 each extending along a Y direction, and a plurality of memory cells 30 provided between the plurality of lower wiring lines 10 and the plurality of upper wiring lines 20, respectively.

The lower wiring lines 10 correspond to word lines and the upper wiring lines 20 correspond to bit lines, or the lower wiring lines 10 correspond to bit lines and the upper wiring lines 20 correspond to word lines. The memory cells 30 each include a magnetoresistance effect element 31 and a selector (switching element) 32 connected in series with each other, and the magnetoresistance effect element 31 and the selector 32 are stacked in a Z direction.

Note that the X direction, the Y direction and the Z direction intersect with each other. More specifically, the X direction, the Y direction and the Z direction are orthogonal to each other.

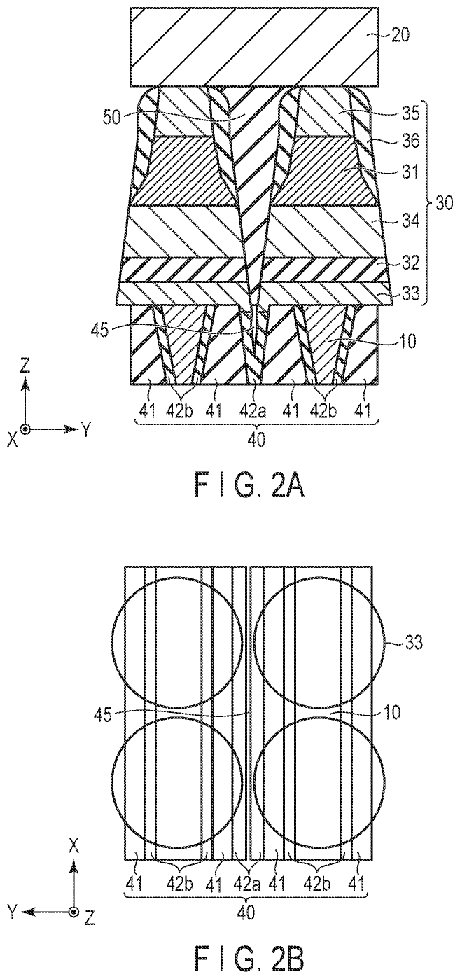

FIG. 2A is a cross-sectional view, which is parallel to the Y direction and the Z direction) schematically showing a detailed configuration of the magnetic memory device of this embodiment. FIG. 2B is a planar pattern view (planar pattern view as viewed from a direction parallel to the Z direction) schematically showing the detailed configuration of the magnetic memory device of this embodiment. Note that in FIG. 2B, part of the configuration shown in FIG. 2A is omitted for convenience.

The magnetic memory device shown in FIGS. 2A and 2B includes lower wiring lines (a lower conductive portion) 10, upper wiring lines 20, memory cells 30, a lower insulating layer 40 and an upper insulating layer 50. FIG. 2A shows two lower wiring lines 10 adjacent to each other along the Y direction and two memory cells 30 adjacent to each other along the Y direction. FIG. 2B shows two lower wiring lines 10 adjacent to each other along the Y direction and two sets of two memory cells 30 adjacent to each other along the Y direction.

Each of the memory cells 30 is provided on the lower insulating layer 40 and the lower wiring lines 10 and includes a magnetoresistance effect element 31, a selector (switching element) 32, a bottom electrode 33, a middle electrode 34, a hard mask 35 and a sidewall insulating layer 36. The magnetoresistance effect element 31, the selector 32, the bottom electrode 33, the middle electrode 34 and the hard mask 35 are stacked in the Z direction, and the selector 32 is provided on a lower layer side of the magnetoresistance effect element 31.

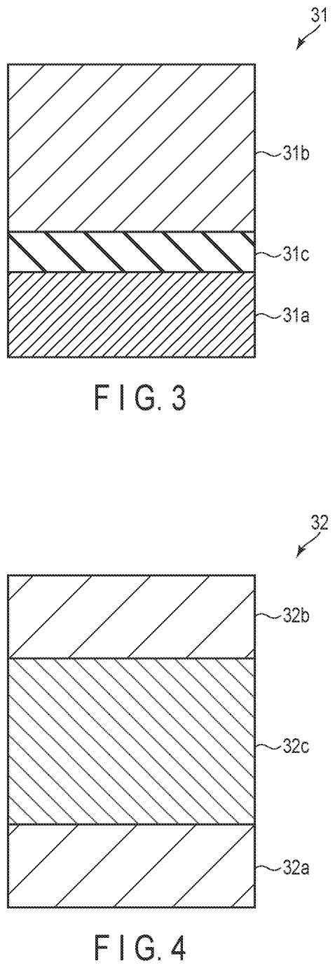

FIG. 3 is a cross-sectional view schematically showing a basic configuration of the magnetoresistance effect element 31.

The magnetoresistance effect element 31 is a magnetic tunnel junction (MTJ) element and includes a storage layer (first magnetic layer) 31a, a reference layer (second magnetic layer) 31b and a tunnel barrier layer (nonmagnetic layer) 31c.

The storage layer 31a is a ferromagnetic layer having a variable magnetization direction. The term “variable magnetization direction” means that the magnetization direction changes for a given write current. The reference layer 31b is a ferromagnetic layer having a fixed magnetization direction. The term “fixed magnetization direction” means that the magnetization direction does not change for a given write current. The tunnel barrier layer 31c is an insulating layer provided between the storage layer 31a and the reference layer 31b.

When the magnetization direction of the storage layer 31a is parallel to the magnetization direction of the reference layer 31b, the magnetoresistance effect element 31 exhibits a low-resistance state having a relatively low resistance. When the magnetization direction of the storage layer 31a is antiparallel to the magnetization direction of the reference layer 31b, the magnetoresistance effect element 31 exhibits a high-resistance state having a relatively high resistance. Therefore, the magnetoresistance effect element 31 can store binary data according to its resistance state.

The magnetoresistance effect element 31 is a spin transfer torque (STT) type magnetoresistance effect element and has perpendicular magnetization. That is, the magnetization direction of the storage layer 31a is perpendicular to the main surface thereof, and the magnetization direction of the reference layer 31b is perpendicular to the main surface thereof.

Note that the magnetoresistance effect element 31 shown in FIG. 3 is a bottom-free type magnetoresistance effect element in which the storage layer 31a is located on a lower side of the reference layer 31b, but a top-free type magnetoresistance effect element in which the storage layer 31a is located on an upper side of the reference layer 31b may be used.

FIG. 4 is a cross-sectional view schematically showing a basic structure of the selector 32.

The selector 32 includes a first electrode 32a, a second electrode 32b, and a selector material layer (switching material layer) 32c provided between the first electrode 32a and the second electrode 32b. The selector material layer 32c has basically an insulating property and is formed, for example, of silicon oxide containing arsenic (As).

FIG. 5 is a diagram schematically illustrates the current-voltage characteristics of the selector 32.

As shown in FIG. 5, the selector 32 changes from an OFF state to an ON state when the voltage applied between its two terminals (between the first electrode 32a and the second electrode 32b) becomes equal to or higher than a predetermined voltage (threshold voltage Vth).

Therefore, when voltage is applied between the lower wiring lines 10 and the upper wiring lines 20 and the voltage applied between the first electrode 32a and the second electrode 32b becomes equal to or higher than the threshold voltage Vth, the selector 32 is set to the ON state. As a result, a current is allowed to flow to the magnetoresistance effect element 31 connected in series with the selector 32, thus enabling writing to or reading from the magnetoresistance effect element 31.

Let us return to the explanation of FIGS. 2A, 2B and 3.

Each of the bottom electrodes 33 is provided on the lower insulating layer 40 and on the corresponding lower wiring line 10. The bottom electrode 33 functions as the bottom electrode of the selector 32(, which corresponds to the first electrode 32a shown in FIG. 4) and is connected to the lower wiring line 10. The bottom electrode 33 is formed of titanium nitride (TiN), for example.

The middle electrode 34 is provided between the magnetoresistance effect element 31 and the selector 32 and functions as the bottom electrode of the magnetoresistance effect element 31 and the top electrode of the selector 32(, which corresponds to the second electrode 32b shown in FIG. 4).

As described above, in this embodiment, the bottom electrode 33 functions as the bottom electrode of the selector 32 and the middle electrode 34 functions as the top electrode of the selector 32. Therefore, in this embodiment, the selector material layer 32c substantially corresponds to the selector 32. In addition to the bottom electrode 33, the first electrode 32a shown in FIG. 4 may be provided, and the first electrode 32a may be included in the selector 32. Similarly, in addition to the middle electrode 34, the second electrode 32b shown in FIG. 4 may be provided and the second electrode 32b may be included in the selector 32.

The hard mask 35 functions as an etching mask to form a pattern of the magnetoresistance effect element 31. Further, the hard mask 35 has the function as the top electrode of the magnetoresistance effect element 31.

The sidewall insulating layer 36 is provided on a side surface of the magnetoresistance effect element 31 and a side surface of the hard mask 35, and has the function of protecting the magnetoresistance effect element 31.

On the lower layer side of each memory cell 30, a structure is provided, which includes a lower insulating layer 40 and corresponding lower wiring line 10.

Each of the lower wiring lines 10 is provided in the lower insulating layer 40 and extends in the X direction. Each pair of lower wirings 10 adjacent to each other along the Y direction are spaced apart from each other. The upper surface of each lower wiring line 10 is connected to the corresponding bottom electrode 33. As viewed from the X direction, the width of each lower wiring line 10 along the Y direction is narrower than the width of the corresponding bottom electrode 33 along the Y direction.

The lower insulating layer 40 includes a void 45 under a region between a pair of memory cells 30 adjacent to each other along the Y direction. The void 45 is located between the respective adjacent pair of lower wiring lines 10 along the Y direction and extends in the X direction. The lower insulating layer 40 includes an insulating layer (first insulating layer) 41, an insulating layer (second insulating layer) 42a, and an insulating layer (third insulating layer) 42b.

The insulating layer 41 is formed of a first insulating material. For example, silicon oxide is used as the first insulating material. The insulating layer 41 includes a pair of portions sandwiching a pair of side surfaces of each lower wiring lines 10 and substantially functions as an interlayer insulating layer.

The insulating layer 42a is formed of a second insulating material different from that of the first insulating material. For example, silicon nitride or aluminum oxide is used as the second insulating material. The insulating layer 42a includes a pair of portions extending in the X direction along a pair of inner side surfaces of the void 45. The upper surface of the insulating layer 42a in its height direction (Z direction) is lower than the upper surface of the insulating layer 41 in its height direction (Z direction). Therefore, the level of the lower surface of the bottom electrode 33 in its height direction (Z direction) located on the insulating layer 42a is lower than the level of the lower surface of the bottom electrode 33 in its height direction (Z direction) located on the insulating layer 41. The bottom portion of the void 45 is closed by the insulating layer 42a.

The insulating layer 42b as well is formed of the second insulating material as in the case of the insulating layer 42a. The insulating layer 42b includes a pair of portions extending in the X direction along a pair of side surfaces of each lower wiring line 10. The level of the upper surface of the insulating layer 42b in the height direction (Z direction) is substantially the same as the level of the upper surface of the insulating layer 41 in the height direction (Z direction).

The upper insulating layer 50 is provided between each adjacent pair of memory cells 30 and is formed, for example, of silicon oxide. The upper insulating layer 50 substantially functions as an interlayer insulating layer.

As described above, in this embodiment, the lower insulating layer 40 has a void 45 under a region between a respective adjacent pair of memory cells 30. With this configuration, when forming a pattern of the memory cells 30, adjacent memory cells 30 can be appropriately separated from each other, thus making it possible to obtain excellent magnetic memory device.

As the memory cells 30 become finer, the space width between each adjacent pair of memory cells 30 inevitably becomes narrower. Therefore, if no void 45 is provided, it is difficult to completely remove the material of the bottom electrode 33 in the region between each adjacent pair of memory cells 30 when forming the pattern of the memory cells 30. In order to completely remove the material of the bottom electrode 33 in the region between each adjacent pair of memory cells 30, it is desirable to etch the lower insulating layer in the portion below the region between each adjacent pair of memory cells 30 and recess the lower insulating layer. However, in this case, the memory cells 30 may be excessively etched, causing damage to the memory cells 30. For example, the sidewall insulating layer 36 may be etched and the magnetoresistance effect element 31 may be severely damaged, undesirably.

In this embodiment, the void 45 is provided under the region between each adjacent pair of memory cells 30, and therefore there is no need to etch the lower insulating layer in the portion under the region between each adjacent pair of memory cells 30. Thus, the material of the bottom electrode 33 can be easily and completely removed in the region between each adjacent pair of memory cells 30. Thus, in this embodiment, each adjacent pair of memory cells 30 can be appropriately separated from each other, and an excellent magnetic memory device can be obtained.

In addition, in this embodiment, the insulating layer 42a is provided along a pair of inner side surfaces of the void 45, and therefore the width of the void 45 can be reduced. In this manner, it is possible to prevent the void 45 from being filled with the material of the bottom electrode 33 when forming the bottom electrode 33. Thus, the pattern of the memory cells 30 can be formed while the void 45 is surely remaining, thus making it possible to properly separate each adjacent pair of memory cells 30 from each other.

Next, a method of manufacturing the magnetic memory device will be described.

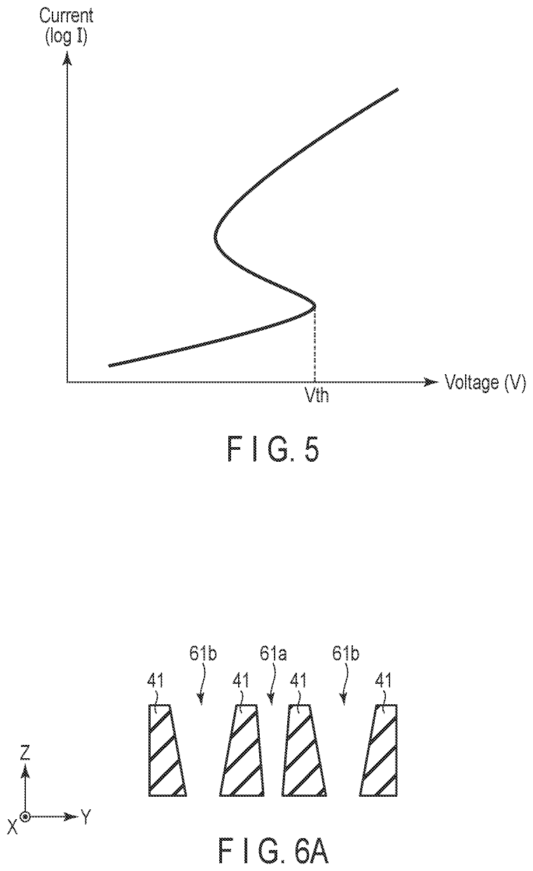

FIGS. 6A and 6B to FIGS. 12A and 12B are each a diagram schematically illustrating the method of manufacturing the magnetic memory device according to this embodiment. FIGS. 6A to 12A are cross-sectional views parallel to the Y direction and the Z direction. FIGS. 6B to 12B are plan views (top views) as seen from a direction parallel to the Z direction.

First, as shown in FIGS. 6A and 6B, a silicon oxide layer is formed as an insulating layer (interlayer insulating layer) 41 on the lower structure (not shown) including a semiconductor substrate (not shown), and the insulating layer 41 is patterned to form trenches 61a and 61b. Note that the width of the trench 61a along the Y direction is less than the width of the trench 61b along the Y direction.

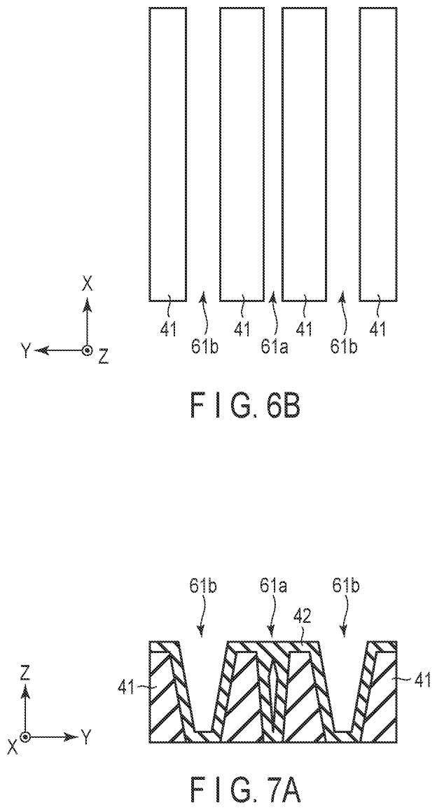

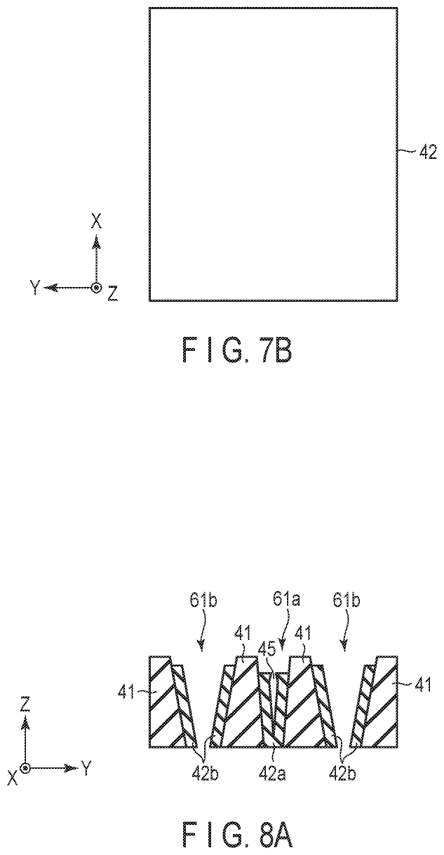

Next, as shown in FIGS. 7A and 7B, a silicon nitride layer or aluminum oxide layer is formed as an insulating layer (spacer insulating layer) 42 on the structure obtained in the processing step shown in FIGS. 6A and 6B.

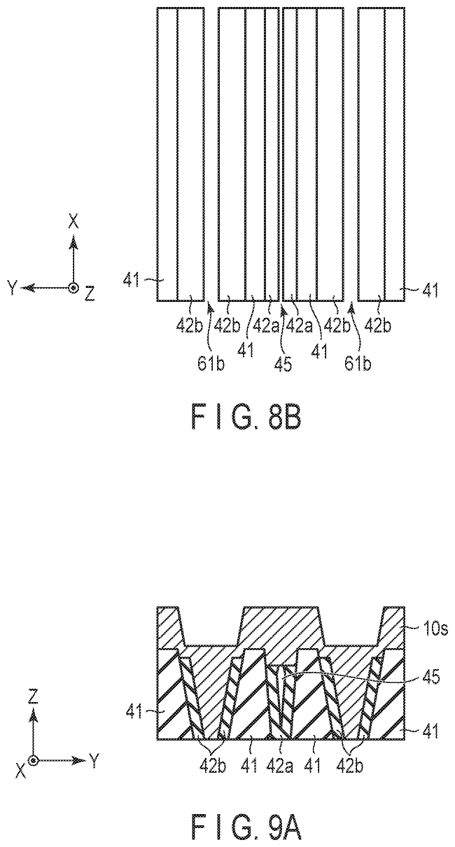

Next, as shown in FIGS. 8A and 8B, the insulating layer 42 is etch-backed. Thus, the insulating layer 42a remains on the side surfaces of the trench 61a and the insulating layer 42b remains on the side surfaces of the trench 61b. Here, the etching rate of the insulating layer 42 is relatively low in the bottom portions of the trench 61a and the trench 61b; therefore the etching is relatively promoted in the upper portion of the insulating layer 42. As a result, the level of the upper surface of the insulating layer 42a and the level of the upper surface of the insulating layer 42b are lower than the level of the upper surface of the insulating layer 41. In particular, the width of the trench 61a is narrow, and therefore the insulating layer 42 is not substantially etched in the bottom portion of the trench 61a, and the etching is more promoted in the upper portion of the trench 61a. As a result, the level of the upper surface of the insulating layer 42a is lower than the level of the upper surface of the insulating layer 42b. Further, a narrow void 45 is formed in a portion interposed by a pair of insulating layers 42a.

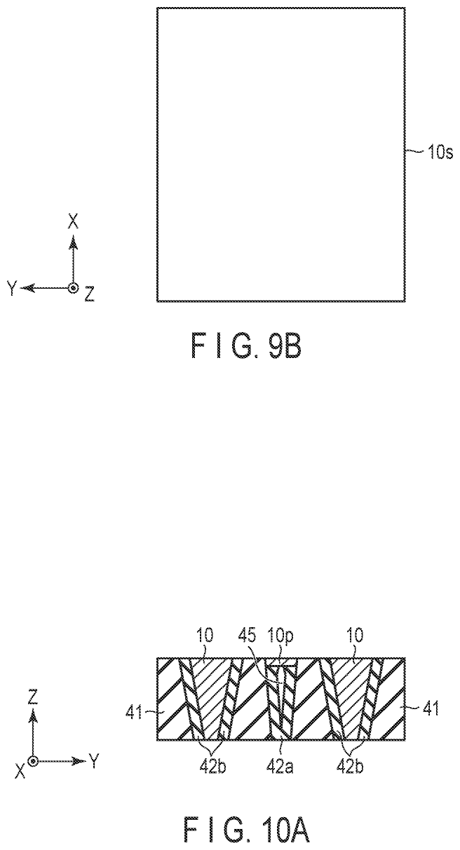

Next, as shown in FIGS. 9A and 9B, a metal layer is formed as a lower wiring layer 10s on the structure obtained in the processing step shown in FIGS. 8A and 8B. At this time, the width of the void 45 is narrow, the lower wiring layer 10s is not formed in the void 45.

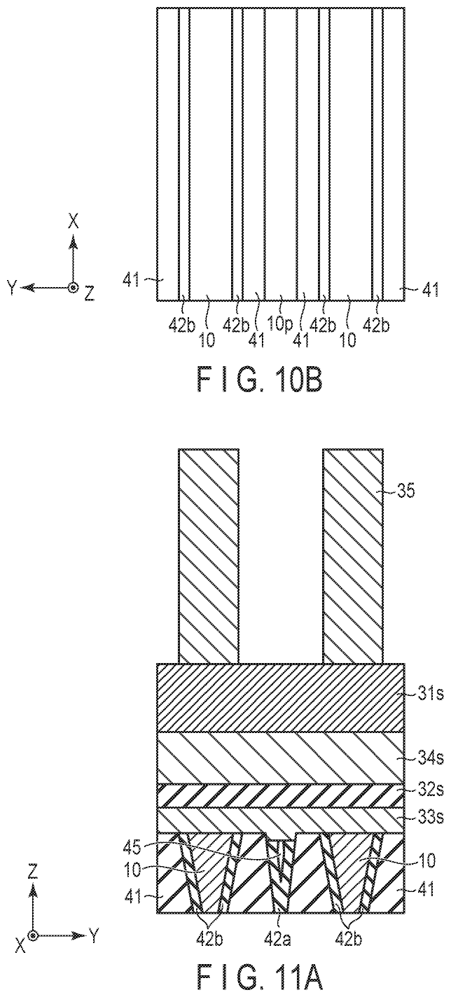

Next, as shown in FIGS. 10A and 10B, a part of the lower wiring layer 10s is removed by chemical mechanical polishing (CMP). As a result, the lower wiring line 10 is obtained. Further, a portion 10p of the lower wiring line layer 10s remains on the insulating layer 42a.

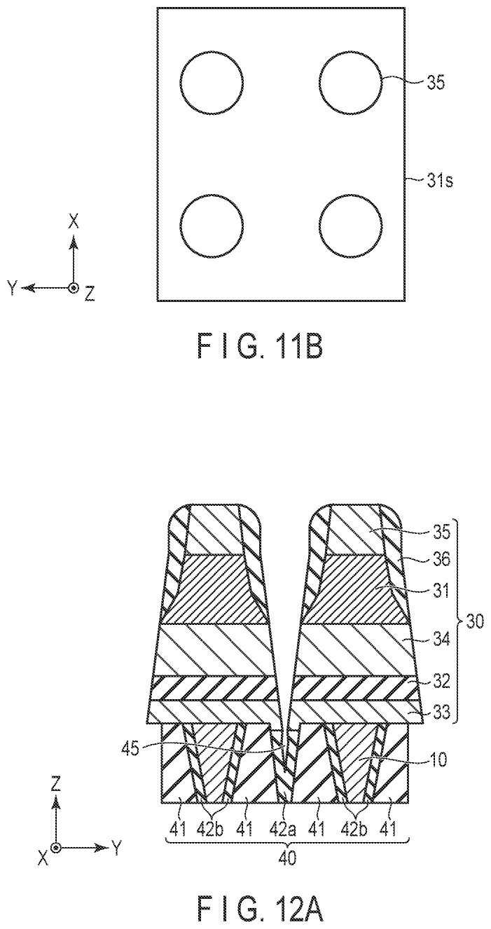

Next, as shown in FIGS. 11A and 11B, a bottom electrode layer 33s, a selector layer 32s, a middle electrode layer 34s and a magnetoresistance effect element layer 31s are formed on the structure obtained in the processing step shown in FIGS. 10A and 10B, and a pattern of the hard mask 35 is formed on the magnetoresistance effect element layer 31s.

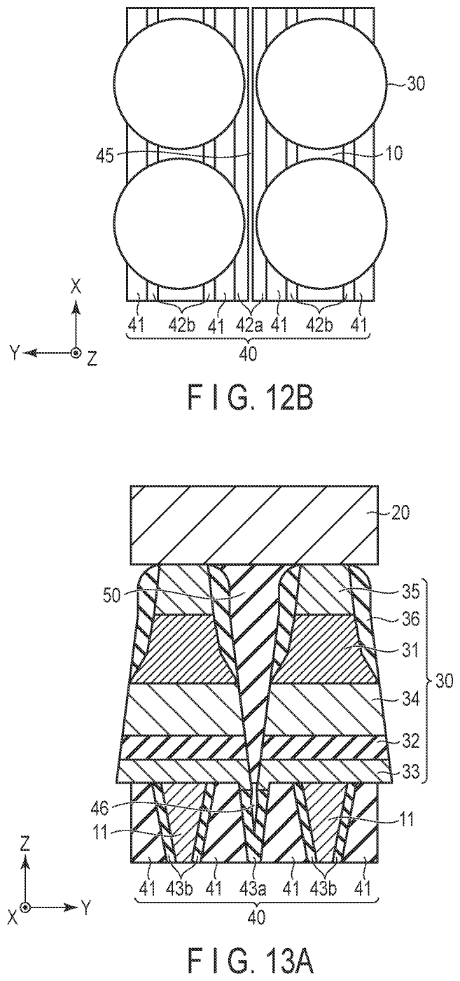

Next, as shown in FIGS. 12A and 12B, the magnetoresistance effect element layer 31s, the middle electrode layer 34s, the selector layer 32s and the bottom electrode layer 33s are etched by ion beam etching (IBE) and reactive ion etching (RIE) using the hard mask 35 as a mask. As a result, a pattern of the magnetoresistance effect element 31, the middle electrode 34, the selector 32 and the bottom electrode 33 is obtained. Further, the sidewall insulating layer 36 is formed on the side surfaces of the magnetoresistance effect element 31 and the hard mask 35. In this way, a plurality of memory cells 30 separated from each other are obtained.

Then, by forming the upper insulating layer 50 and the upper wiring line 20, a structure such as shown in FIGS. 2A and 2B is obtained.

In the manufacturing method described above, when forming the memory cells 30 in the etching process shown in FIGS. 12A and 12B, the void 45 is provided under the region between memory cells 30 adjacent to each other. With this configuration, the material of the bottom electrode 33 can be easily and completely removed in the region between adjacent memory cells 30. Therefore, adjacent memory cells 30 can be surely separated from each other, thereby making it possible to obtain an excellent magnetic memory device.

### Second Embodiment

Next, the second embodiment will be described. Note that basic items are similar to those of the first embodiment, and the explanation of the items already described in the first embodiment will be omitted.

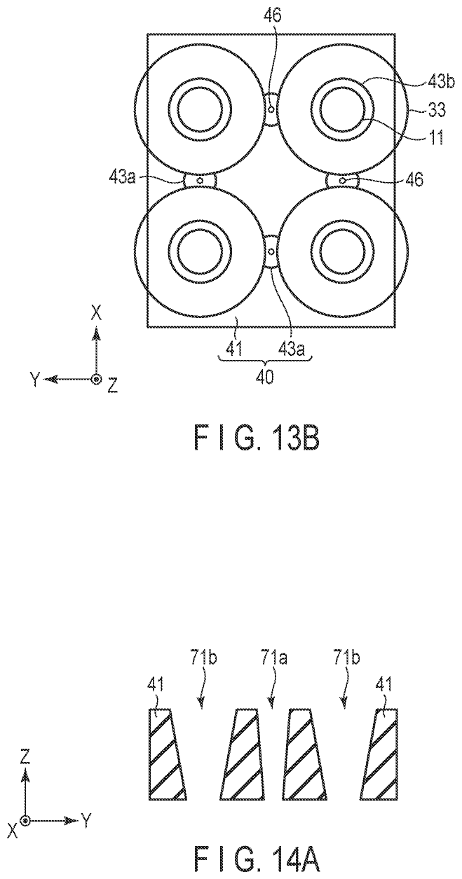

FIG. 13A is a cross-sectional view (parallel to the Y direction and the Z direction) schematically showing a detailed configuration of the magnetic memory device according to the second embodiment. FIG. 13B is a planar pattern view (as viewed from a direction parallel to the Z direction) schematically showing the detailed configuration of the magnetic memory device of this embodiment. Note that in FIG. 13B, part of the configuration shown in FIG. 13A is omitted for convenience.

The magnetic memory device shown in FIGS. 13A and 13B includes plug electrodes (lower conductive portions) 11, an upper wiring line 20, memory cells 30, a lower insulating layer 40 and an upper insulating layer 50. In this embodiment, the plug electrode 11 is provided in place of the lower wiring line 10 shown in the first embodiment. The upper surface of the plug electrode 11 is connected to the bottom electrodes 33, and the lower wiring line (not shown) is connected to the lower surfaces of the plug electrodes 11. Each of the bottom electrodes 33 is provided on the lower insulating layer 40 and on the corresponding plug electrode 11.

Each of the plug electrodes 11 is provided in the lower insulating layer 40. Plug electrodes 11 adjacent to each other are separated from each other. That is, the plug electrodes 11 adjacent to each other along the X direction are separated from each other and the plug electrodes 11 adjacent to each other along the Y direction are separated from each other. As viewed from the Z direction, the pattern of each plug electrode 11 is located on an inner side of the pattern of the corresponding bottom electrode 33. Thus, as viewed from the X direction, the width of each plug electrode 11 along the Y direction is narrower than the width of the corresponding bottom electrode 33 along the Y direction. Similarly, as viewed from the Y direction, the width of each plug electrode 11 along the X direction is narrower than the width of the corresponding bottom electrode 33 along the X direction.

The lower insulating layer 40 includes a void 46 under the region between each adjacent pair of memory cells 30. The void 46 is located between each adjacent pair of plug electrodes 11. More specifically, the void 46 is located between the plug electrodes 11 adjacent to each other along the X direction and the void 46 is located between the plug electrodes 11 adjacent to each other along the Y direction. The lower insulating layer 40 includes an insulating layer (first insulating layer) 41, an insulating layer (second insulating layer) 43a and an insulating layer (third insulating layer) 43b.

The insulating layer 41 is basically similar to that of the first embodiment and is formed of the first insulating material. For example, silicon oxide is used as the first insulating material. The insulating layer 41 includes a portion surrounding the side surface of the plug electrode 11 and substantially functions as an interlayer insulating layer.

The insulating layer 43a is formed of a second insulating material different from the first insulating material. For example, silicon nitride or aluminum oxide is used as the second insulating material. The insulating layer 43a is provided along the inner side surface of the void 46. The level of the upper surface of the insulating layer 43a in the height direction (Z direction) is lower than the level of the upper surface of the insulating layer 41 in the height direction (Z direction). Therefore, the level of the lower surface of the bottom electrode 33 in the height direction (Z direction), located on the insulating layer 43a is lower than the level of the lower surface of the bottom electrode 33 in the height direction (Z direction), located on the insulating layer 41. The bottom portion of the void 46 is closed by the insulating layer 43a.

The insulating layer 43b as well is formed of the second insulating material as in the case of the insulating layer 43a. The insulating layer 43b includes a portion provided along the side surface of each plug electrode 11. The level of the upper surface of the insulating layer 43b in the height direction (Z direction) is substantially the same as the level of the upper surface of the insulating layer 41 in the height direction (Z direction).

As described above, in this embodiment as well, as in the case of the first embodiment, the lower insulating layer 40 includes a void 46 under the region between each adjacent pair of memory cells 30. Therefore, as in the first embodiment, when forming the pattern of the memory cells 30, the adjacent memory cells 30 can be appropriately separated from each other, thus making it possible to obtain an excellent magnetic memory device.

Further, in this embodiment, the insulating layer 43a is provided along the inner side surface of the void 46. With this configuration, the diameter of the void 46 can be reduced, and therefore, it is possible to prevent the void 46 from being filled with the material of the bottom electrode 33 when forming the bottom electrode 33. Therefore, it is possible to form a pattern of memory cells 30 while the void 46 is surely remaining, and thus adjacent memory cells 30 can be appropriately separated from each other.

Next, the method of manufacturing the magnetic memory device according to this embodiment will be described.

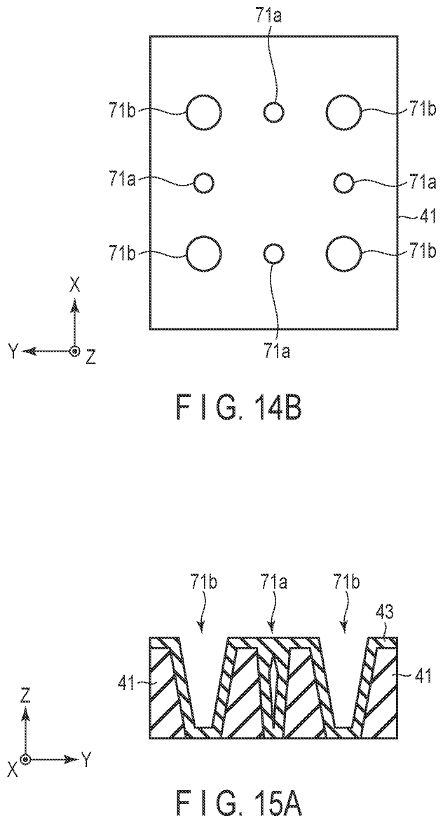

FIGS. 14A and 14B to FIGS. 20A and 20B are diagrams each schematically illustrating the method of manufacturing the magnetic memory device of this embodiment. FIGS. 14A to 20A are cross-sectional views parallel to the Y direction and the Z direction. FIGS. 14B to 20B are planar views (top views) as seen from a direction parallel to the Z direction.

First, as shown in FIGS. 14A and 14B, a silicon oxide layer is formed as an insulating layer (interlayer insulating layer) 41 on the lower structure (not shown) including the semiconductor substrate (not shown), and the insulating layer 41 is patterned to form holes 71a and 71b. The diameter of the hole 71a is less than that of the hole 71b.

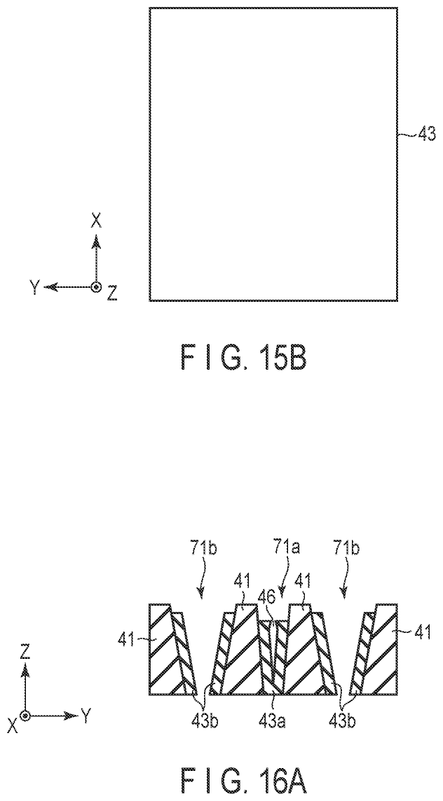

Next, as shown in FIGS. 15A and 15B, a silicon nitride layer or aluminum oxide layer is formed as an insulating layer (spacer insulating layer) 43 on the structure obtained in the processing step shown in FIGS. 14A and 14B.

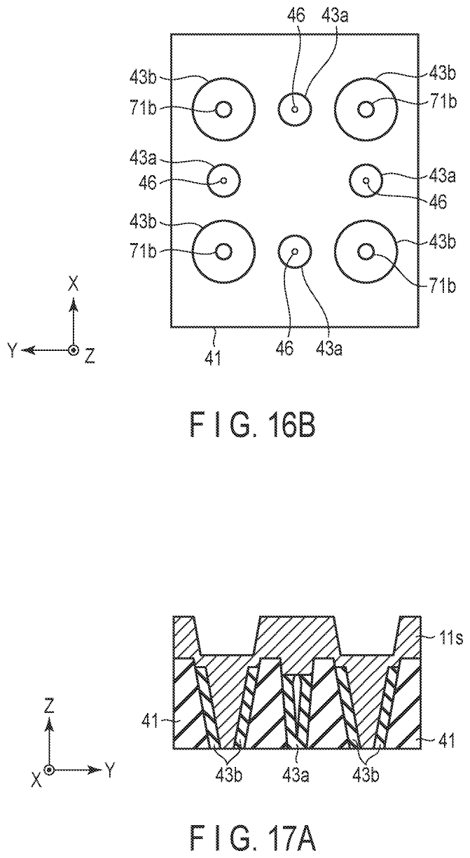

Next, as shown in FIGS. 16A and 16B, the insulating layer 43 is etch-backed. Thus, the insulating layer 43a remains on the side surface of the hole 71a and the insulating layer 43b remains on the side surface of the hole 71b. For same reasons similar to those explained in connection with FIGS. 8A and 8B of the first embodiment, the level of the upper surface of the insulating layer 43a and the upper surface of the insulating layer 43b is lower than the level of the upper surface of the insulating layer 41, and the level of the upper surface of the insulating layer 43a is lower than the level of the upper surface of the insulating layer 43b. Further, a void 46 having a small diameter is formed on an inner side of the insulating layer 43a.

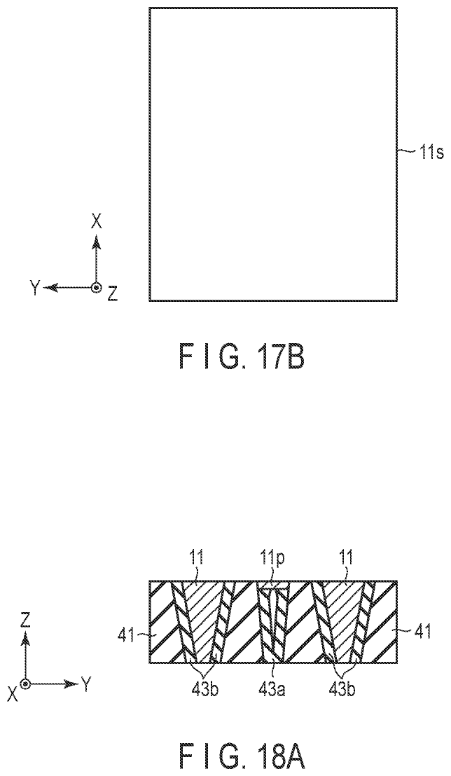

Next, as shown in FIGS. 17A and 17B, a metal layer is formed as the plug electrode layer 11s on the structure obtained in the processing step shown in FIGS. 16A and 16B. At this time, since the diameter of the void 46 is small, the plug electrode layer 11s is not formed inside the void 46.

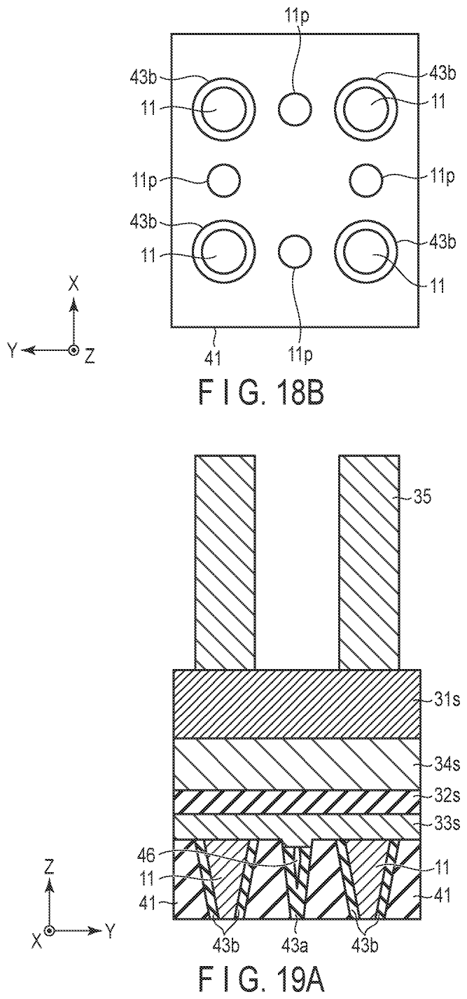

Next, as shown in FIGS. 18A and 18B, a part of the plug electrode layer 11s is removed by CMP. Thus, the plug electrode 11 is obtained. A portion 11p of the plug electrode layer 11s remains on the insulating layer 43a.

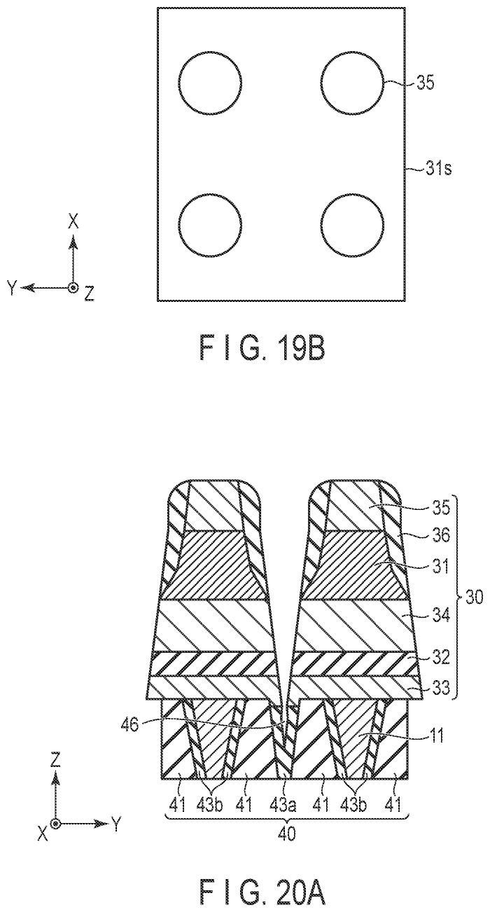

Next, as shown in FIGS. 19A and 19B, the bottom electrode layer 33s, the selector layer 32s, the middle electrode layer 34s and the magnetoresistance effect element layer 31s are formed on the structure obtained in the processing step shown in FIGS. 18A and 18B, and a pattern of the hard mask 35 is formed on the magnetoresistance effect element layer 31s.

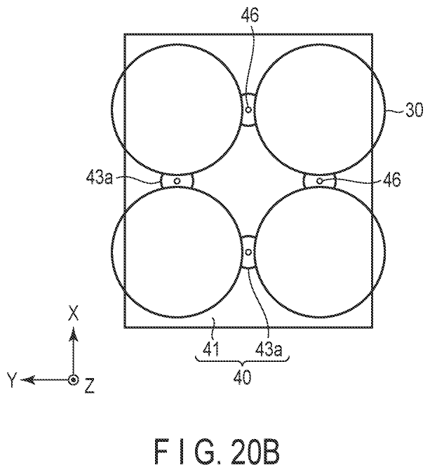

Next, as shown in FIGS. 20A and 20B, etching is performed in a manner similar to that of the processing step in FIGS. 12A and 12B of the first embodiment to form a pattern of magnetoresistance effect element 31, the middle electrode 34, the selector 32 and the bottom electrode 33. Furthermore, a sidewall insulating layer 36 is formed on the side surfaces of the magnetoresistance effect element 31 and the hard mask 35. In this way, a plurality of memory cells 30 separated from each other can be obtained.

Then, by forming an upper insulating layer 50 and upper wiring lines 20, such a structure as shown in FIGS. 13A and 13B is obtained.

According to the manufacturing method described above, when forming the memory cells 30 in the etching process shown in FIGS. 20A and 20B, a void 46 is provided under the region between adjacent memory cells 30. With this configuration, as in the case of the first embodiment, the material of the bottom electrode 33 can be easily and completely removed in the region between the adjacent memory cells 30. In this manner, the adjacent memory cells 30 can be reliably separated from each other, thereby making it possible to obtain an excellent magnetic memory device.

Note that in the first and second embodiments described above, the selector 32 is provided on a lower layer side of the magnetoresistance effect element 31, but the selector 32 may be provided on an upper layer side of the magnetoresistance effect element 31.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory device comprising:
a lower insulating layer;
a first lower conductive portion provided in the lower insulating layer;
a second lower conductive portion provided in the lower insulating layer, and arranged to be apart from the first lower conductive portion and adjacent to the first lower conductive portion in a first direction;
a first memory cell provided on the lower insulating layer and on the first lower conductive portion, and including a first magnetoresistance effect element, a first switching element and a first bottom electrode connected to the first lower conductive portion which are stacked in a second direction intersecting the first direction;
a second memory cell provided on the lower insulating layer and on the second lower conductive portion, arranged adjacent to the first memory cell in the first direction, and including a second magnetoresistance effect element, a second switching element and a second bottom electrode connected to the second lower conductive portion which are stacked in the second direction,
wherein
as viewed from a third direction intersecting the first and second directions, a width of the first lower conductive portion in the first direction is less than a width of the first bottom electrode in the first direction, and a width of the second lower conductive portion in the first direction is less than a width of the second bottom electrode in the first direction, and
the lower insulating layer has a void under a region between the first memory cell and the second memory cell.

2. The magnetic memory device of claim 1, wherein
the first lower conductive portion is a first lower wiring line extending along the third direction;
the second lower conductive portion is a second lower wiring line extending along the third direction, and
the void is located between the first lower wiring line and the second lower wiring line and extends along the third direction.

3. The magnetic memory device of claim 2, wherein
the first bottom electrode is provided on the lower insulating layer and on the first lower wiring line, and
the second bottom electrode is provided on the lower insulating layer and on the second lower wiring line.

4. The magnetic memory device of claim 2, wherein
the lower insulating layer includes:
a first insulating layer formed of a first insulating material and including a pair of portions sandwiching a pair of side surfaces of the first lower wiring line, and a pair of portions sandwiching a pair of side surfaces of the second lower wiring line; and
a second insulating layer formed of a second insulating material different from the first insulating material and including a pair of portions extending along the third direction along a pair of inner side surfaces of the void.

5. The magnetic memory device of claim 4, wherein
a level of an upper surface of the second insulating layer in a height direction is lower than a level of an upper surface of the first insulating layer in the height direction.

6. The magnetic memory device of claim 4, wherein
a bottom portion of the void is closed by the second insulating layer.

7. The magnetic memory device of claim 4, wherein
the lower insulating layer further includes a third insulating layer formed of the second insulating material and including a pair of portions extending along the third direction along the pair of side surfaces of the first lower wiring line and a pair of portions extending along the third direction along the pair of side surfaces of the second lower wiring line.

8. The magnetic memory device of claim 1, wherein
the first lower conductive portion is a first plug electrode,
the second lower conductive portion is a second plug electrode, and
the void is located between the first plug electrode and the second plug electrode.

9. The magnetic memory device of claim 8, wherein
the first bottom electrode is provided on the lower insulating layer and on the first plug electrode, and
the second bottom electrode is provided on the lower insulating layer and on the second plug electrode.

10. The magnetic memory device of claim 8, wherein
the lower insulating layer includes:
a first insulating layer formed of a first insulating material and including a portion which surrounds a side surface of the first plug electrode and a portion which surrounds a side surface of the second plug electrode; and
a second insulating layer formed of a second insulating material different from the first insulating material and provided along an inner side surface of the void.

11. The magnetic memory device of claim 10, wherein
a level of an upper surface of the second insulating layer in a height direction is lower than a level of an upper surface of the first insulating layer in the height direction.

12. The magnetic memory device of claim 10, wherein
a bottom portion of the void is closed by the second insulating layer.

13. The magnetic memory device of claim 10, wherein
the lower insulating layer further includes a third insulating layer formed of the second insulating material and including a portion provided along the side surface of the first plug electrode and a portion provided along the side surface of the second plug electrode.

14. The magnetic memory device of claim 1, wherein
the first switching element is provided on a lower layer side of the first magnetoresistance effect element and connected to the first bottom electrode, and
the second switching element is provided on a lower layer side of the second magnetoresistance effect element and connected to the second bottom electrode.

15. The magnetic memory device of claim 1, wherein
each of the first and second magnetoresistance effect elements includes:
a first magnetic layer having a variable magnetization direction;
a second magnetic layer having a fixed magnetization direction; and
a non-magnetic layer located between the first magnetic layer and the second magnetic layer.

16. The magnetic memory device of claim 1, wherein
each of the first and second switching elements changes from an off state to an on state when a voltage applied between two terminals thereof becomes equal to or higher than a predetermined voltage.
